(19) United States
(12) Patent Application Publication
(10) Pub. No.: US 2002/0130691 A1
(43) Pub. Date: Sep. 19, 2002

(54) Method and apparatus for fast lock of delay lock loop

(76) Inventor: Paul A. Silvestri, Meridian, ID (US)

Correspondence Address: Michael G. Fletcher, Fletcher, Yoder & Van Someren, P.O. Box 692289, Houston, TX, 77269-2289, US

(21) Appl. No.: 09/809,717

(22) Filed: Mar. 15, 2001

(51) Int. Cl. H03L 7/06

(52) U.S. Cl. 327/158

(57) ABSTRACT

A method and apparatus to dynamically set the insertion point of a delay line control shift register based on the current cycle time. A string of delay elements equivalent to the delay elements in a delay lock loop (DLL) are laid out in the opposite direction compared to the DLL delay elements. Both strings of delay elements receive a synchronous input signal such as an external clock signal. The output clock signal of the DLL is phase-shifted relative to the external clock signal such that data removed from a device such as a synchronous dynamic random access memory (SDRAM) device is synchronous with the external clock signal. When a DLL reset command is issued, the information from the string of delay elements is captured and used to set the insertion point of the DLL to the locked or phase-equal point. This allows the DLL to quickly lock on any frequency upon reset of the DLL.

### BACKGROUND OF THE INVENTION

1. Field of the Invention

The present invention relates generally to memory devices and, more particularly, to reducing the lock time of memory devices which implement a delay locked loop to synchronize input signals to the memory devices.

2. Description of the Related Art

This section is intended to introduce the reader to various aspects of art which may be related to various aspects of the present invention which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Microprocessor-controlled integrated circuits are used in a wide variety of applications. Such applications include personal computers, vehicle control systems, telephone networks, and a host of consumer products. As is well known, microprocessors are essentially generic devices that perform specific functions under the control of a software program. This program is stored in a memory device which is coupled to the microprocessor. Not only does the microprocessor access memory devices to retrieve the program instructions, but it also stores and retrieves data created during execution of the program in one or more memory devices.

There are a variety of different memory devices available for use in microprocessor-based systems. The type of memory device chosen for a specific function within a microprocessor-based system generally depends upon which features of the memory are best suited to perform the particular function. Memory manufacturers provide an array of innovative fast memory chips for various applications, including Dynamic Random Access Memories (DRAM), which are lower in cost but have slower data rates, and Static Random Access Memories (SRAM), which are more costly but offer higher data rates. Although both DRAMs and SRAMs are making significant gains in speed and bandwidth, even the fastest memory devices cannot match the speed requirements of most microprocessors. Regardless of the type of memory, the solution for providing adequate memory bandwidth depends on system architecture, the application requirements, and the processor, all of which help determine the best memory type for a given application. Limitations on speed include delays in the chip, the package, and the system. Thus, significant research and development has been devoted to finding faster ways to access memory and to reduce or hide latency associated with memory accesses.

Because microprocessor technology enables current microprocessors to operate faster than current memory devices, circuit techniques for increasing the speed of memory devices are often implemented. For example, one type of memory device that can contribute to increased processing speeds in the computer system is a Synchronous Dynamic Random Access Memory (SDRAM). An SDRAM differs from a standard DRAM in that the SDRAM includes input and output latches to hold information from and for the processor under the control of (i.e., synchronous with) the system clock. Because input information (i.e., addresses, data, and controls signals) is latched, the processor may perform other tasks while waiting for the SDRAM to finish its task, thereby reducing processor wait states. After a predetermined number of clock cycles during which the SDRAM is processing the processor's request, the processor may return to the SDRAM and obtain the requested information from the output latches.

A technique for increasing the speed of an SDRAM is to implement a Double Data Rate (DDR) SDRAM. In a DDR memory device, the data transfer rate is twice that of a regular memory device, because the DDR's input/output data can be strobed twice for every clock cycle. That is, data is sent on both the rising and falling edges of the clock signal rather than just the rising edge of the clock signal as in typical Single Data Rate (SDR) systems.

In high speed memory devices such as DDR SDRAMs it is often desirable to synchronize the timing of certain signals, such as clock signals, which may be external to the memory devices with internally generated clock signals or other external signals. One means of synchronizing signals is by implementing a delay locked loop (DLL) circuit. The DLL circuit is used to create an output signal that is matched in terms of frequency and/or phase to the input signal, which may be an external clock signal, for example. In conventional DLL circuits, an input buffer is used to receive an input signal, such as an external clock signal, and to transmit the signal to one or more delay lines. The delay line includes a number of delay elements. A phase detector may be used to compare the input clock signal to the output signal by using a feedback loop. The information can then be fed from the phase detector to a shift register to move through the delay elements in the delay line incrementally to search for a match. When the input signal and output signal are equal, the signals are synchronized, and the DLL is considered locked. Disadvantageously, this method of synchronizing signals often takes many clock cycles to find the locking point. If, for example, a delay line has 100 delay elements, it may take 100 clock cycles to achieve a lock.

Thus, it would be desirable to provide a memory device having a circuit which dynamically locks a DLL in a minimum number of cycles. This would provide a locking method and apparatus which coincides with the ever-increasing speed of microprocessing and memory access.

The present invention may address one or more of the problems set forth above.

### BRIEF DESCRIPTION OF THE DRAWINGS

The foregoing and other advantages of the invention will become apparent upon reading the following detailed description and upon reference to the drawings in which:

FIG. 1 illustrates a block diagram of an exemplary processor-based device in accordance with the present technique;

FIG. 2 illustrates a block diagram of an exemplary memory device used in the processor-based device of FIG. 1;

FIG. 3 illustrates a block diagram of a typical delay lock loop used to synchronize the output data from the memory device of FIG. 2 with the system clock;

FIG. 4 illustrates a block diagram of a fast lock delay lock loop in accordance with the present technique;

FIG. 5 illustrates a schematic diagram of one embodiment of the delay line and the mirror delay line illustrated in FIG. 4; and

FIG. 6 illustrates a schematic diagram of one embodiment of the shift register illustrated in FIG. 4.

### DETAILED DESCRIPTION OF SPECIFIC EMBODIMENTS

One or more specific embodiments of the present invention will be described below. In an effort to provide a concise description of these embodiments, not all features of an actual implementation may be described in the specification. It should be appreciated that in the development of any such actual implementation, as in any engineering or design project, numerous implementation-specific decisions are made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

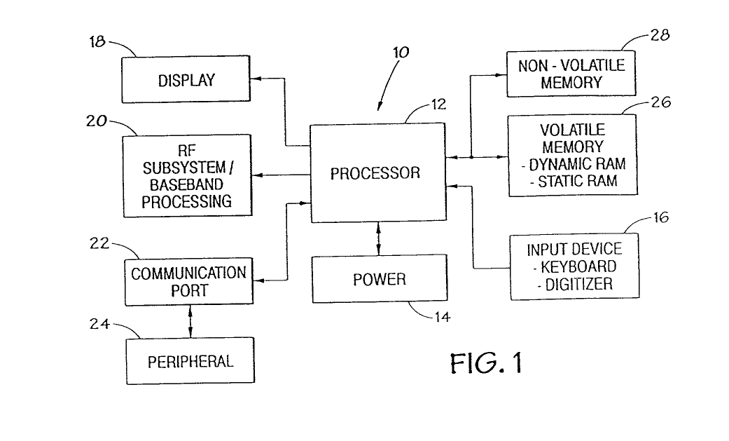

Turning now to the drawings, and referring initially to FIG. 1, a block diagram depicting an exemplary processor-based device, generally designated by the reference numeral 10, is illustrated. The device 10 may be any of a variety of different types, such as a computer, pager, cellular telephone, personal organizer, control circuit, etc. In a typical processor-based device, a processor 12, such as a microprocessor, controls many of the functions of the device 10.

The device 10 typically includes a power supply 14. For instance, if the device 10 is portable, the power supply 14 would advantageously include permanent batteries, replaceable batteries, and/or rechargeable batteries. The power supply 14 may also include an A/C adapter, so that the device may be plugged into a wall outlet, for instance. In fact, the power supply 14 may also include a D/C adapter, so that the device 10 may be plugged into a vehicle's cigarette lighter, for instance.

Various other devices may be coupled to the processor 12, depending upon the functions that the device 10 performs. For instance, a user interface 16 may be coupled to the processor 12. The user interface 16 may include an input device, such as buttons, switches, a keyboard, a light pin, a mouse, and/or a voice recognition system, for instance. A display 18 may also be coupled to the processor 12. The display 18 may include an LCD display, a CRT, LEDs, and/or an audio display. Furthermore, an RF subsystem/baseband processor 20 may also be coupled to the processor 12. The RF subsystem/baseband processor 20 may include an antenna that is coupled to an RF receiver and to an RF transmitter (not shown). A communication port 22 may also be coupled to the processor 12. The communication port 22 may be adapted to be coupled to a peripheral device 24, such as a modem, a printer, or a computer, for instance, or to a network, such as a local area network or the Internet.

Because the processor 12 controls the functioning of the device 10 generally under the control of software programming, memory is coupled to the processor 12 to store and facilitate execution of the software program. For instance, the processor 12 may be coupled to volatile memory 26, which may include dynamic random access memory (DRAM), static random access memory (SRAM), Double Data Rate (DDR) memory, etc. The processor 12 may also be coupled to non-volatile memory 28. The non-volatile memory 28 may include a read only memory (ROM), such as an EPROM or Flash Memory, to be used in conjunction with the volatile memory. The size of the ROM is typically selected to be just large enough to store any necessary operating system, application programs, and fixed data. The volatile memory, on the other hand, is typically quite large so that it can store dynamically loaded applications. Additionally, the non-volatile memory 28 may include a high capacity memory such as a disk drive, tape drive memory, CD ROM drive, DVD, read/write CD ROM drive, and/or a floppy disk drive.

The volatile memory 26 may include a number of SDRAMs which implement DDR technology. As mentioned previously, the SDRAM differs from a DRAM in that the SDRAM is controlled synchronously with a timing source, such as the system clock. To accomplish synchronous control, latches are used to provide data and other information on the inputs and outputs of the SDRAM. Thus, in a read operation for example, the processor 12 may visit a data output latch a predetermined number of clock cycles after issuing the read request. The predetermined number of clock cycles typically corresponds to the amount of time needed to access the requested data, move the data to the output latch, and allow the data to stabilize. The data is clocked out of the output latch synchronous with the system clock which provides the timing source for the processor 12. Synchronization of the data read from the output latch with the system clock is generally implemented via a delay lock loop (DLL) circuit, as preciously discussed and as further discussed in more detail below. In general, the DLL locks the data output signal to the system clock by shifting the output data in time such that it is nominally aligned with the system clock. Thus, the DLL can compensate for timing delays introduced by various components in the SDRAM.

Write operations also are performed synchronous with a timing source, such as the system clock or other externally provided timing source. Thus, data may be clocked into an input latch and written to the memory array under control of a write clock provided from the external device which is performing the write operation. Delay lock loops may also be implemented to synchronize write data with the write clock.

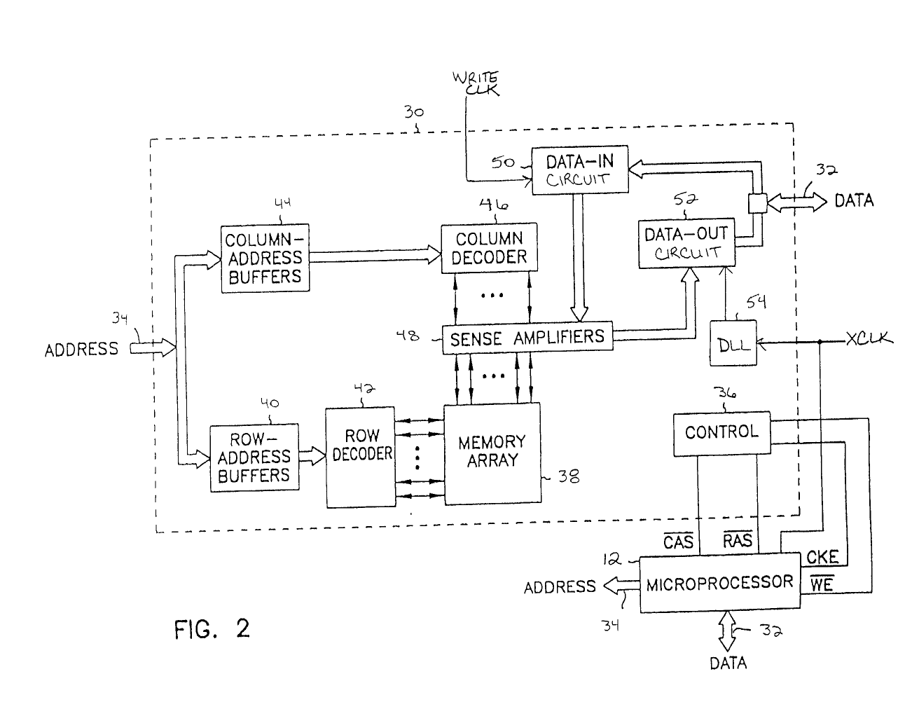

Turning now to FIG. 2, a block diagram depicting an exemplary embodiment of a DDR SDRAM is illustrated. The description of the DDR SDRAM 30 has been simplified for illustrative purposes and is not intended to be a complete description of all features of a DDR SDRAM. The present technique may not be limited to DDR SDRAMs, and may be equally applicable to other synchronous random access memory devices, and other devices for use in communication applications, such as double-edge triggered applications, which may benefit from strict adherence to timing. Those skilled in the art will recognize the various devices may be used in the implementation of the present invention.

Control, address, and data information provided over a memory bus are represented by individual inputs to the DDR SDRAM 30. These individual representations are illustrated by a databus 32, address lines 34, and various discrete lines directed to control logic 36. As is known in the art, the SDRAM 30 includes a memory array 38 which comprises rows and columns of addressable memory cells. Each memory cell in a row is coupled to a word line. Additionally, each memory cell in a column is coupled to a bit line. Each cell in the memory array 38 typically includes a storage capacitor and an access transistor as is conventional in the art.

The SDRAM 30 interfaces with, for example, a microprocessor 12 through address lines 34 and data lines 32. Alternatively, the SDRAM 30 may interface with other devices, such as a SDRAM controller, a microcontroller, a chip set, or other electronic system. The microprocessor 12 also may provide a number of control signals to the SDRAM 30. Such signals may include row and column address strobe signals RAS and CAS, a write enable signal WE, a clock enable signal CKE, and other conventional control signals. The control logic 36 controls the many available functions of the SDRAM 30. In addition, various other control circuits and signals not detailed herein contribute to the SDRAM 30 operation as known to one of ordinary skill in the art.

A row address buffer 40 and a row decoder 42 receive and decode row addresses from row address signals provided on the address lines 34. Each unique row address corresponds to a row of cells in the memory array 38. The row decoder 42 typically includes a word line driver, an address decoder tree, and circuitry which translates a given row address received from row address buffers 40 and selectively activates the appropriate word line of the memory array 38 via the word line drivers.

A column address buffer 44 and a column decoder 46 receive and decode column address signals provided on the address lines 34. The column decoder 46 also determines when a column is defective and the address of a replacement column. The column decoder 46 is coupled to sense amplifiers 48. The sense amplifiers 48 are coupled to complementary pairs of bit lines of the memory array 38.

The sense amplifiers 48 are coupled to data-in (i.e., write) circuitry 50 and data-out (i.e., read) circuitry 52. The data-in circuitry 50 and the data-out circuitry 52 include data drivers and latches, as will be discussed in detail below. During a write operation, the data bus 32 provides data to the data-in circuitry 50. The sense amplifier 48 receives data from the data-in circuitry 50 and stores the data in the memory array 38 as a charge on a capacitor of a cell at an address specified on the address line 34. In one embodiment, the data bus 32 is an 8-bit data bus carrying data at 400 MHz or higher.

During a read operation, the DDR SDRAM 30 transfers data to the microprocessor 12 from the memory array 30. Complementary bit lines for the accessed cell are equilibrated during a precharge operation to a reference voltage provided by an equilibration circuit and a reference voltage supply. The charge stored in the accessed cell is then shared with the associated bit lines. The sense amplifier 48 detects and amplifies a difference in voltage between the complementary bit lines. Address information received on address lines 34 selects a subset of the bit lines and couples them to complementary pairs of input/output (I/O) wires or lines. The I/O wires pass the amplified voltage signals to the data-out circuitry 52 and eventually out to the data bus 32.

The data-out circuitry 52 may include a data driver (not shown) to drive data out onto the data bus 32 in response a read request directed to the memory array 38. Further, the data-out circuitry 52 may include a data latch (not shown) to latch the read data until it is driven on the data bus 32 by the data driver. The timing source for the data latch may be provided by a delay lock loop (DLL) 54 which provides a shifted clock signal (CLKOUT) which is synchronous with the external system clock (XCLK), thus locking the output data signal (DATA) on the data bus 32 to the system clock.

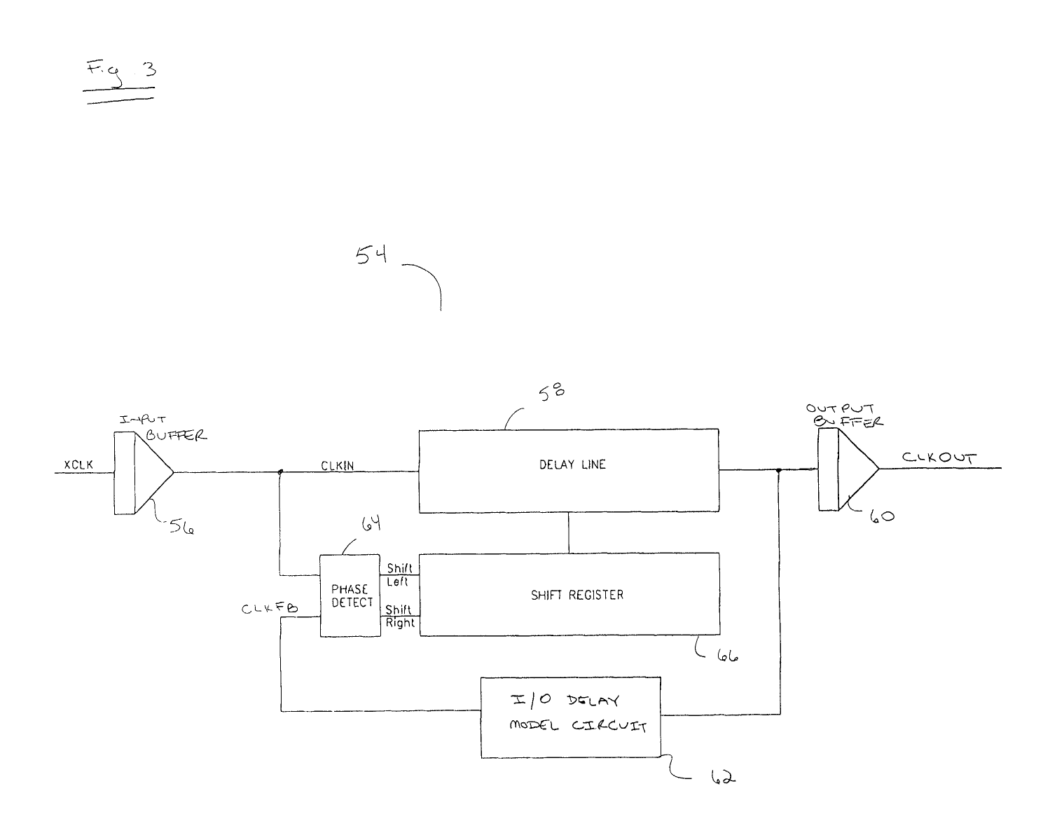

An exemplary embodiment of a typical DLL 54 is illustrated in FIG. 3. Differences in alignment between signals having the same frequency may arise due to propagation delays inherent in each of the various components in the system through which the signal of interest passes as well as propagation delays caused by varying lengths of signal buses in the system. For example, it may be desirable to drive various components in the system with a reference clock signal generated by an external source and to obtain an output signal from the driven components which is synchronous with the reference clock signal. To reach the various components, the reference clock signal may be transmitted through various buffers and traverse buses of various lengths. Thus, when received at the input pin of a particular component, the clock signal may no longer be aligned (i.e., is out of phase) with the reference clock signal.

A conventional DLL, such as the DLL 54, implements synchronization by forcing at least one of the edges of the clock signal for the data-out circuit 52 to align with a corresponding edge of the reference clock signal XCLK, thus locking the data output signal (DATA) to the reference clock signal. The DLL 54 detects a phase difference between two signals and generates a corresponding feedback signal representative of the difference which is used to introduce or remove delay elements as needed to attain alignment of the data output signal (DATA) with the reference clock signal (XCLK).

In the DLL 54 illustrated in FIG. 3, a reference clock signal XCLK is received by an input buffer 56 and provided to a delay line 58 as a buffered clock signal CLKIN. The output of the delay line 58 is connected to an output buffer 60 and an input/output (I/O) delay model circuit 62. The I/O delay model circuit 62 provides a feedback clock signal (CLKFB) which is transmitted to a phase detector 64 for comparison with the buffered reference clock signal CLKIN. The phase detector 64 determines whether a difference exists between the phase of the feedback clock signal CLKFB and the buffered reference clock signal CLKIN. The detected difference determines the amount of delay to be introduced in or removed from the delay line 58 by a shift register 66 such that the buffered reference clock signal CLKIN may be shifted by an appropriate amount to produce an output clock signal CLKOUT that aligns, or locks, with the reference clock signal XCLK.

When the DLL 54 has locked the data output signal CLKOUT to the reference clock signal XCLK, then no difference should exist between the phases of the buffered clock signal CLKIN and the clock feedback signal CLKFB. Thus, a DLL is locked when the total delay in the forward path is equal to the total delay in the feedback path. Expressed another way:

d_{forward}=t_{input buffer}+t_{delay line}+t_{ouput buffer}

d_{feedback}=t_{delay line}+t_{model}

d_{forward}=d_{feedback}

where d_{forward} corresponds to the delay between the reference clock signal and the data output signal; d_{feedback} corresponds to the delay in the I/O delay model circuit; t_{input buffer} corresponds to the delay of the input buffer 56; t_{delay line} corresponds to the delay in the delay line of the delay line 58; t_{output buffer} corresponds to the delay of the output buffer 60; and t_{model} corresponds to the delay in the I/O delay model circuit 62. Thus, to achieve phase lock,

t_{model}=t_{input buffer}+t_{output buffer}

Thus, the I/O delay model circuit 62 introduces delays in the feedback path corresponding to the delay (t_{input buffer}) introduced by the input buffer 56 and the delay (t_{output buffer}) introduced by the output buffer 60. Because t_{model} is a constant, when the input changes frequency, the t_{delay} line should change in response to the changing input. The phase detector 64 will output a shift left or shift right depending no whether the buffered clock signal CLKIN is too fast or too slow. The shift register 66 then shifts the tap point of the delay line 58 by one delay element. The process is repeated until the input signals to the phase detector 64 are phase equal and the DLL 54 is locked. Disadvantageously, this process may take numerous clock cycles to achieve a signal lock. Since the DLL 54 is generally configured to track various frequencies, the delay line 58 generally comprises a large number of delay elements, such as 100, for example. The DLL 54 may be initialized with a DLLRST command to set the delay line 58 to a predetermined value to start comparison. The phase detector 64 will facilitate the adding or subtracting of delay until a lock is achieved.

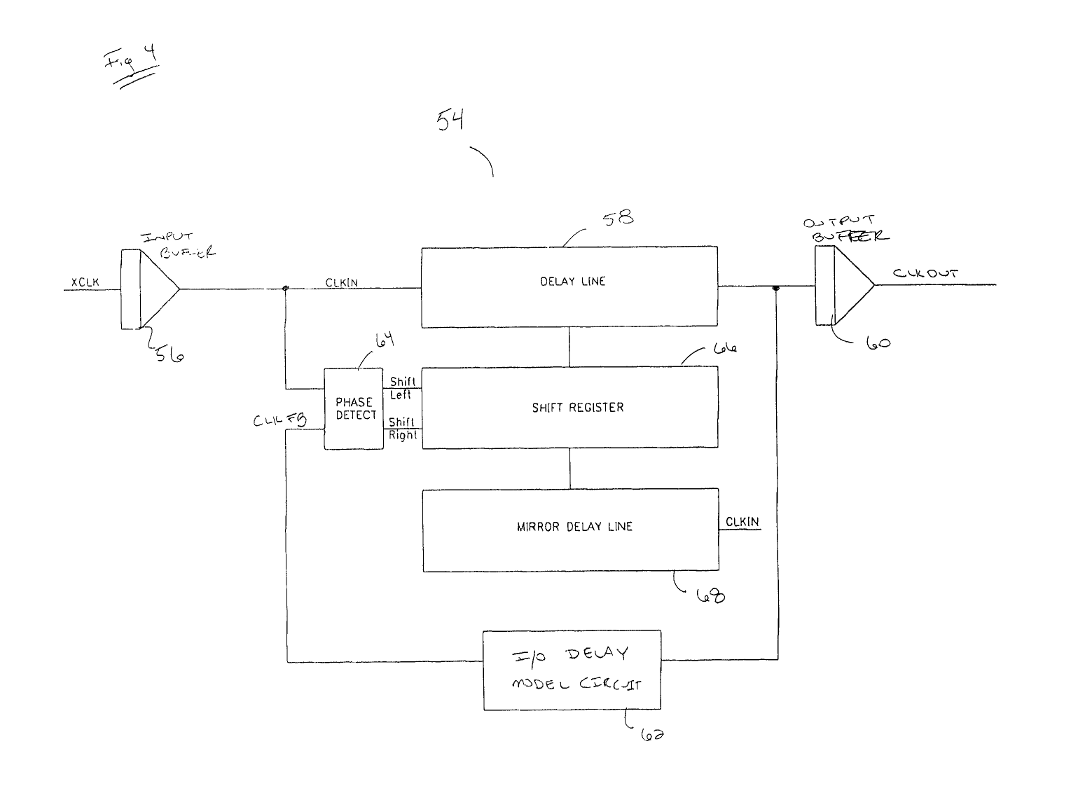

FIG. 4 illustrates a DLL in accordance with the present technique of a fast lock DLL 54′. For simplicity, the reference numbers to elements common to those discussed with reference to FIG. 3 have been repeated. In the embodiment illustrated in FIG. 4, the DLL 54′ includes a mirror delay line 68. The mirror delay line 68 is used to set the tap point in the shift register 66 dynamically upon initialization. The mirror delay line 68 may be identical to the delay line 58 with the exception of additional circuitry to reset the shift register 66 during DLLRST. Because the mirror delay line 68 has the same number of delay elements as the delay line 58, the amount of delay needed for the forward path to lock the DLL can be determined by the mirror delay line 68, without necessitating the delivery of additional clock cycles. The buffered input signal CLKIN is delivered to both the delay line 58 and the mirror delay line 68. When the DLL 54′ is reset, the number of delay elements or stages through which the buffered input signal CLKIN propagates in the mirror delay line 68 will be equal to the number of stages need to lock the DLL 54′ at the given frequency. The mirror delay line 68 is monitored by the shift register 66. Once a second clock cycle is delivered, the shift register 66 is initialized with the amount of delay needed in the forward path to achieve a lock.

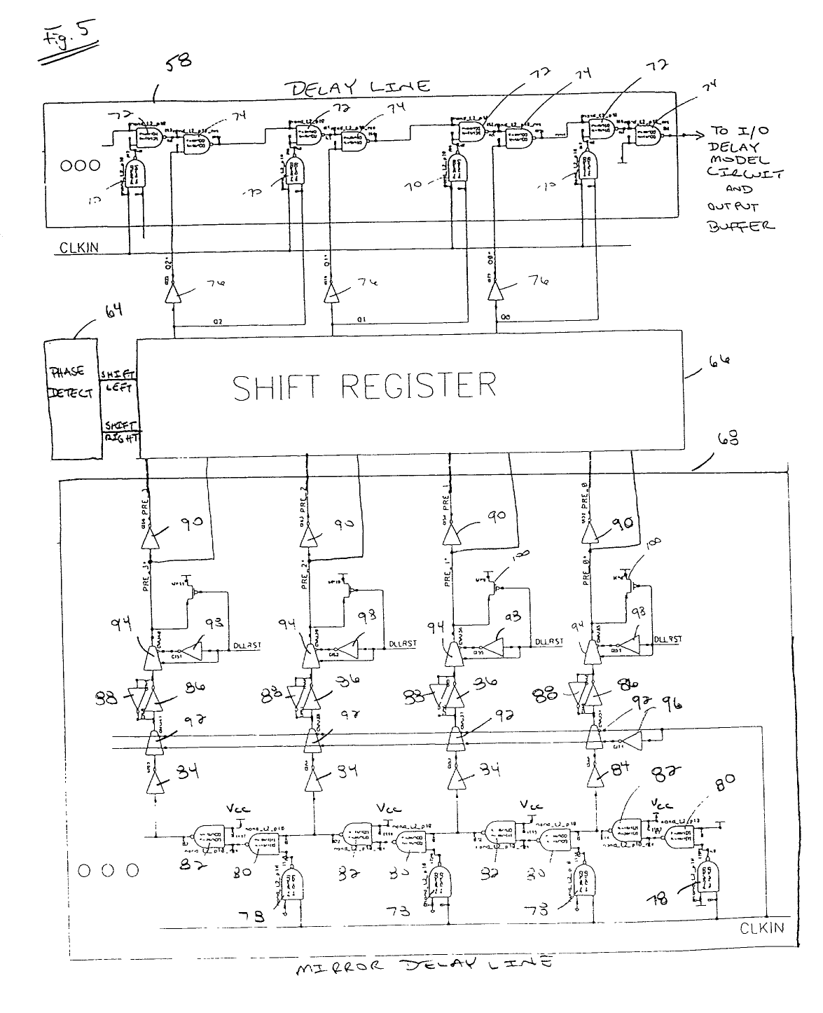

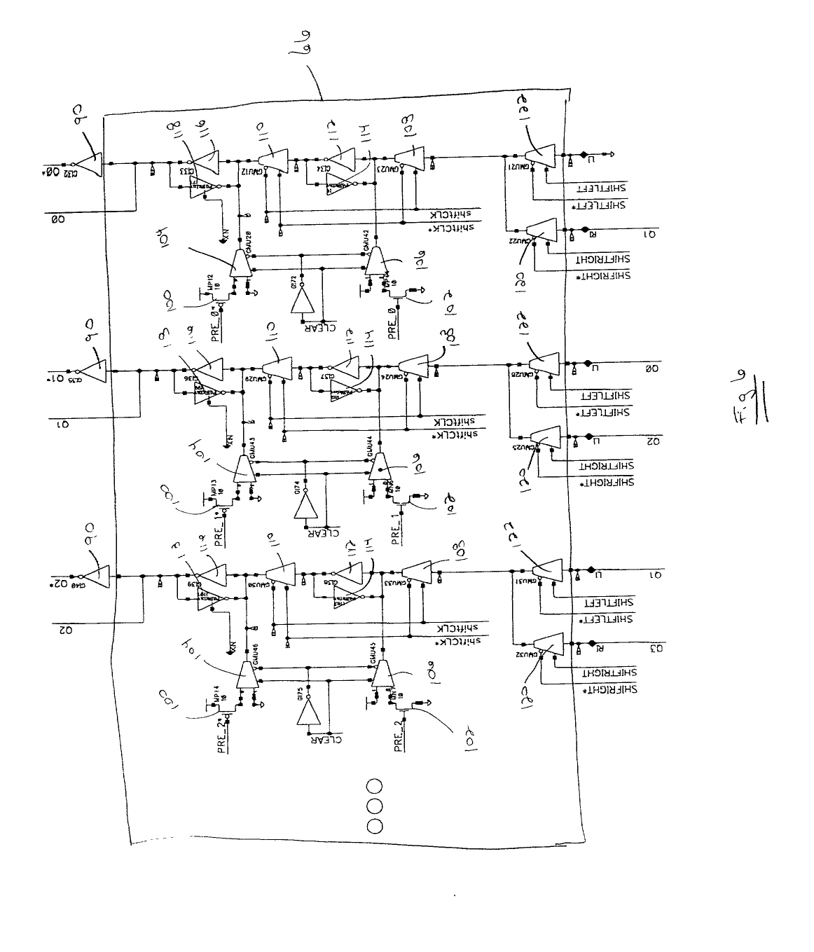

As one skilled in the art can appreciate, the delay line 58, mirror delay line 68, and shift register 66 may comprise a variety of different logical elements to achieve the functions described above. FIG. 5 illustrates a schematic of one embodiment of the delay line 58 and the mirror delay line 68 in accordance with the present technique. FIG. 6 illustrates a schematic of one embodiment of the shift register 66 in accordance with the present technique. These illustrations are shown only to provide exemplary schematics for the embodiments described herein and should in no way be interpreted to limit the scope of the techniques described with reference to FIG. 4 above.

As described above, the delay line 58 includes a plurality of delay elements or stages which each introduce some fixed amount of delay to the buffered input signal CLKIN. By shifting the buffered input signal CLKIN to a certain position or “tap” along the delay line 58, the buffered input signal CLKIN can be phase locked to the feedback signal CLKFB. Here, each delay stage comprises NAND gates 70, 72, and 74. Only four delay stages are illustrated in the delay line 58, but it should be understood that the delay line 58 will likely comprise many more delay stages to increase the range of frequencies over which the DLL 54′ may properly function. Each stage is connected in a series chain with respect to each other and receives the buffered input signal CLKIN and a signal Q0*−Qn−1*, where “n” represents the number of stages present in the delay line 58, respectively to provide the shifting information necessary to achieve a DLL lock. The signals Q0*-Qn* may be delivered from the shift register 66 through an inverter 76. The output of the delay line 58 is delivered to the I/O delay model circuit 62 and the output buffer 60, as illustrated in FIG. 4.

Similarly, the mirror delay line 68 includes a plurality of delay elements or stages which each introduce some fixed amount of delay to the buffered input signal CLKIN. Here, each delay stage comprises NAND gates 78, 80, and 82. Each stage is connected in a series chain with respect to each other and receives the buffered input signal CLKIN at NAND gate 78 to provide the shifting information necessary to achieve a DLL lock. The buffered input signal CLKIN passes through the mirror delay line 68 and delivers the tap point information to the shift register 66 to achieve a DLL lock.

Each NAND gate 82 of each stage of the mirror delay line 68 delivers a signal to the shift register 66 through a plurality of inverters 84, 86, 88, and 90, and multiplexors 92 and 94 which are configured to provide the appropriate tapping point by enabling the stage of the mirror delay line 68 which will produce a DLL lock. The multiplexor 92 also receives the inversion of the buffered input signal CLKIN through an inverter 96. Each path is further enabled during DLLRST using an inverter 98 and a transistor 100.

FIG. 6 illustrates one embodiment of the shift register 66 wherein the shift register is dynamically initialized by the mirror delay line 68 to set the insertion point, rather than relying on a DLL reset signal DLLRST to reset the shift register 66 to a known state, such as all zeros. As previously described, the latter method of initializing the shift register 66 to a known state is less desirable since it may require many clock cycles to determine the insertion point to achieve a lock of the DLL. As with the delay line 58 and the mirror delay line 68, the shift register 66 includes a plurality of stages, each stage being identical. For simplicity, all like elements are given common reference numerals.

As illustrated in FIG. 5, each stage of the shift register 66 receives a set of output signals (PRE_n and PRE_n*, where “n” represents the stage number) which provide the shift register 66 with information set the insertion point of the buffered input signal CLKIN such that it is phase-matched with the external clock signal XCLK. The output signals from each stage of the mirror delay line 66 are delivered to the shift register through transistors 100 and 102. The signals are delivered through the transistors 100 and 102 to multiplexors 104 and 106, respectively. The output of the multiplexors 104 and 106 are further combined through multiplexors 108 and 110 and inverters 112, 114, 116, and 118. Further, the shift register 66 receives shift left and shift right locking commands from the phase detector 64 through multiplexors 120 and 122. Finally, after the insertion point is set from the information provided to the shift register 66 by the mirror delay line 68, the shift register provides output signals Qn and Qn* to the delay line 58 which will provide the information necessary to phase-lock the DLL.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A system comprising:
a processor; and
a memory device coupled to the processor, the memory device comprising a delay lock loop (DLL) circuit, the DLL circuit comprising:
a first delay line comprising a first plurality of delay elements and configured to receive an input signal and to produce an output signal, and wherein the input signal has a first phase and the output signal has a second phase;
a second delay line comprising a second plurality of delay elements, and configured to receive the input signal and to produce an indicator correlative to a locking point in the delay lock loop;
a phase detector configured to compare the first phase of the input signal and the second phase of the output signal; and
a shift register coupled between the first delay line and the second delay line and configured to receive a shift signal from the phase detector, the shift signal providing information correlative to the locking point, and wherein the shift register is further configured to receive the output from the second delay line and to transmit the information to the first delay line to shift the phase of the input signal in response to the shift signal.

2. The system, as set forth in claim 1, wherein the memory device comprises a synchronous dynamic random access memory (SDRAM) device.

3. The system, as set forth in claim 1, wherein the input signal comprises a clock signal, the clock signal being generated by a device external to the memory device.

4. The system, as set forth in claim 3, wherein the clock signal comprises a buffered clock signal.

5. The system, as set forth in claim 1, wherein the first plurality of delay elements comprises the same number of delay elements as the second plurality of delay elements.

6. The system, as set forth in claim 1, wherein the first plurality of delay elements are substantially similar to the second plurality of delay elements.

7. The system, as set forth in claim 1, wherein each of the first plurality of delay elements comprises a plurality of NAND gates, one of each of the plurality of NAND gates configured to receive the input signal.

8. The system, as set forth in claim 1, wherein each of the second plurality of delay elements comprises a plurality of NAND gates, one of each of the plurality of NAND gates configured to receive the input signal.

9. The system, as set forth in claim 1, wherein the locking point of the delay lock loop is achieved when the first phase is equal to the second phase.

10. The system, as set forth in claim 1, wherein the shift register is dynamically initialized by the second delay line at power-up.

11. The system, as set forth in claim 10, wherein the initialization comprises setting the locking point in the shift register.

12. The system, as set forth in claim 11, where the initialization comprises setting the locking point in the first delay line.

13. A delay lock loop circuit configured to match the phase of an input signal and an output signal, the circuit comprising:
a first delay line comprising a first plurality of delay elements and configured to receive an input signal and to produce an output signal, and wherein the input signal has a first phase and the output signal has a second phase;
a second delay line comprising a second plurality of delay elements, and configured to receive the input signal and to produce an indicator correlative to a locking point in the delay lock loop;
a phase detector configured to compare the first phase of the input signal and the second phase of the output signal; and
a shift register coupled between the first delay line and the second delay line and configured to receive a shift signal from the phase detector, the shift signal providing information correlative to the locking point, and wherein the shift register is further configured to receive the output from the second delay line and to transmit the information to the first delay line to shift the phase of the input signal in response to the shift signal.

14. The circuit, as set forth in claim 13, wherein the input signal comprises a clock signal, the clock signal being generated by a device external to the memory device.

15. The circuit, as set forth in claim 14, wherein the clock signal comprises a buffered clock signal.

16. The circuit, as set forth in claim 13, wherein the first plurality of delay elements comprises the same number of delay elements as the second plurality of delay elements.

17. The circuit, as set forth in claim 13, wherein the first plurality of delay elements are substantially similar to the second plurality of delay elements.

18. The circuit, as set forth in claim 13, wherein each of the first plurality of delay elements comprises a plurality of NAND gates, one of each of the plurality of NAND gates configured to receive the input signal.

19. The circuit, as set forth in claim 13, wherein each of the second plurality of delay elements comprises a plurality of NAND gates, one of each of the plurality of NAND gates configured to receive the input signal.

20. The circuit, as set forth in claim 13, wherein the locking point of the delay lock loop is achieved when the first phase is equal to the second phase.

21. The circuit, as set forth in claim 13, wherein the shift register is dynamically initialized by the second delay line at power-up.

22. The circuit, as set forth in claim 21, wherein the initialization comprises setting the locking point in the shift register.

23. The circuit, as set forth in claim 22, where the initialization comprises setting the locking point in the first delay line.

24. A method of phase-matching the input and the output of a delay lock loop, comprising the acts of:
providing an input signal to a first delay line and a second delay line;
comparing the phase of the input signal to a phase of an output signal, the output signal being produced by the first delay line;
transmitting the input signal through the second delay line to obtain an insertion point;
providing the insertion point information from the second delay line to a shift register;
shifting a starting point of the shift register to match the insertion point information; and
providing the starting point information from the shift register to the first delay line such that the phase of the output of the first delay line is equal to the phase of the input signal.

25. The method of phase-matching, as set forth in claim 24, wherein each of the first delay line and the second delay line comprise a plurality of delay elements.

26. The method of phase-matching, as set forth in claim 25, wherein the first delay line and the second delay line comprise substantially the same delay elements.

27. The method of phase-matching, as set forth in claim 24, wherein the input signal comprises a clock signal, the clock signal being generated by a device external to the delay lock loop.

28. The method of phase-matching, as set forth in claim 27, wherein the clock signal comprises a buffered clock signal.

29. The method of phase-matching, as set forth in claim 25, wherein the act of comparing comprises the act of comparing the phase of the input signal to the phase of an output signal, the output signal being produced by the first delay line and filtered through an input/output delay model circuit.

30. The method of phase-matching, as set forth in claim 29, wherein the input/output delay model circuit comprises delay elements to compensate for delays in the input signal caused by input and output buffers.

31. The method of phase-matching, as set forth in claim 25, wherein the act of providing the insertion point information from the second delay line to a shift register occurs in response to a delay lock loop reset signal.
